(19) United States
(12) Patent Application Publication
(10) Pub. No.: US 2006/0199310 A1
(43) Pub. Date: Sep. 7, 2006

(54) Semiconductor integrated circuit and semiconductor device

(76) Inventors: Yukio Nakabayashi, Yokohama-shi (JP); Junji Koga, Yokosuka-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/366,552

(22) Filed: Mar. 3, 2006

(30) Foreign Application Priority Data
Mar. 4, 2005 (JP) P2005-60843

(51) Int. Cl. H01L 21/82; H01L 23/02

(52) U.S. Cl. 438/128; 257/678

(57) ABSTRACT

A semiconductor integrated circuit includes a substrate having a main surface to which a first stress is applied; a first channel conductive field effect transistor placed in a first region of the main surface of the substrate, the carrier mobility of a channel of the first channel conductive field effect transistor being improved by the first stress; and a second channel conductive field effect transistor placed in a second region of the main surface of the substrate, and receiving a second stress at a channel thereof, the second stress being opposite to the first stress, the carrier mobility of the channel of the second channel conductive field effect transistor being improved by the second stress, and the second region being independent from the first region.

### CROSS REFERENCE TO RELATED APPLICATIONS

This application is based upon and claims the benefit of priority from prior Japanese Patent Application No. 2005-060,843 filed on Mar. 4, 2005, the entire contents of which are incorporated by reference herein.

### BACKGROUND OF THE INVENTION

1. Filed of the Invention

The present invention relates to a semiconductor integrated circuit and a semiconductor device, and more particularly relates to a semiconductor integrated circuit and a semiconductor device which include complementary transistors on a substrate.

2. Description of the Related Art

In order to accelerate processing of an LSI (Large Scale Integrated Circuit), it is necessary to speed up the operation of MOSFETs (Metal Oxide Semiconductor Field Effect Transistors) constituting the LSI. However, effects of such acceleration become gradually diminished due to a variety of parasitic phenomena accompanying conventional scale-down techniques. In order to overcome this problem, it has been proposed to strain a channel region of the MOSFET and to improve the carrier mobility. In “International Technology Roadmap for Semiconductors” 2003 Edition, it is planned for the high performance specification to introduce the straining process in 2008.

Channels are strained depending upon their materials or by process control.

At present, a logic LSI uses a CMOS (Complementary MOS) circuit in view of low power consumption and so on. With the CMOS circuit, the carrier mobility of the electrons and holes has to be accelerated. However, the electrons and holes are required different strain (tensioned or compressed, uni-axially or bi-axially), to be accelerated. When the CMOS is integrated, it is necessary to separately create elements appropriate for electrons and elements appropriate for holes in adjacent minute regions. It is possible to improve the performance of a single element while it is very difficult to accomplish high performance in CMOS integrated circuit.

Japanese Patent Laid-Open Publication No. 2000-277,683 has proposed to thin and soften semiconductor chips, for example. Such semiconductor chips reduce a warpage of a package and improve reliability thereof. However, the semiconductor chips of the foregoing publication are intended to improve the reliability, but not to realize high speed operation.

The MOSFET including strained channels are effective in improving raising the mobility, but suffers a problem that it is very difficult to improve the performance when actually integrating CMOSs.

The present invention has been contemplated in order to overcome the foregoing technical problems of the related art, and is intended to provide a semiconductor integrated circuit and a semiconductor device in which the operation of a complementary IGFET (Insulated Gate Field Effect transistor) can be accelerated with ease.

### BRIEF SUMMARY OF THE INVENTION

In accordance with a first aspect of the embodiment, a semiconductor integrated circuit includes a substrate having a main surface to which a first stress is applied; a first channel conductive field effect transistor placed in a first region of the main surface of the substrate, the carrier mobility of a channel of the first channel conductive field effect transistor being improved by the first stress; and a second channel conductive field effect transistor placed in a second region of the main surface of the substrate, and receiving a second stress at a channel thereof, the second stress being opposite to the first stress, the carrier mobility of the channel of the second channel conductive field effect transistor being improved by the second stress, and the second region being independent from the first region.

In accordance with a second aspect of the embodiment, a semiconductor integrated circuit includes a substrate having a main surface which is subject to a compressive stress; a p-channel conductive field effect transistor placed on a first region of the main surface of the substrate; and a n-channel conductive field effect transistor placed on a second region of the main surface of the substrate, the second region being independent from the first region.

In accordance with a third aspect of the embodiment, a semiconductor integrated circuit includes a stressed substrate; a first channel conductive field effect transistor placed over a neutral plane of the stress of the substrate, and receiving a first stress; and a second channel conductive field effect transistor placed under the neutral plane of the stress of the substrate, and receiving a second stress opposite to the first stress.

In accordance with a fourth aspect of the embodiment, a semiconductor device includes a curved die pad; and the semiconductor integrated circuit of the first aspect, the semiconductor integrated circuits being curved in accordance with a contour of the die pad and being stressed.

In accordance with a final aspect of the embodiment, a semiconductor device includes the semiconductor integrated circuit of the first aspect; a printed circuit board on which the semiconductor integrated circuit are mounted; first bump electrodes provided between a rear surface of the substrate of the semiconductor integrated circuit and a center of a front surface of the printed circuit board, the first bump electrode being shaped in accordance with a target shape of the substrate; and second bump electrodes provided at peripheral areas of the rear surface of the substrate and the front surface of the printed circuit board, the second bump electrode being shaped in accordance with the target shape of the substrate, and having a size different from a size of the first bump electrodes.

### BRIEF DESCRIPTION OF THE DRAWINGS

The same reference numerals refer to the same parts throughout various Figures.

FIG. 1 is a cross section showing the configuration of a semiconductor integrated circuit according to a first embodiment of the invention;

FIG. 2 is a cross section showing the configuration of a semiconductor device according to the first example of the invention;

FIG. 3 schematically shows a curved semiconductor chip and a curved die pad of the semiconductor device of FIG. 2;

FIG. 4 is a cross section of a compressible insulating film deposited on a p-channel conductive IGFET of the semiconductor device of FIG. 2;

FIG. 5 is a cross section of the p-channel conductive IGFET in which a source and a drain are made of strained SiGe or compressive metal silicide (Ti, Ni or Co silicide);

FIG. 6 is a cross section of a semiconductor device including a concave die pad;

FIG. 7 is a cross section of an extensible insulating film deposited on an n-channel conductive IGFET in the semiconductor device of FIG. 6;

FIG. 8 is a cross section of source and drain electrodes made of extensible metal suicide in a semiconductor chip of the semiconductor device of FIG. 6;

FIG. 9A is a schematic cross section of a semiconductor device in which an Si region is covered by a material having a Young's modulus smaller than that of Si;

FIG. 9B schematically shows a curved state of the semiconductor shown in FIG. 9A;

FIG. 10 is a perspective view of a uni-axially curved die pad;

FIG. 11 is a perspective view of a bi-axially curved die pad;

FIG. 12 is a graph showing the relationship between a uniaxial stress and a hole mobility progress rate;

FIG. 13 is a graph showing the relationship between thickness of a nitride film and an electron drive current progress rate;

FIG. 14 is a graph showing the relationship between a bi-axial stress and a mobility progress rate;

FIG. 15 is a cross section of a semiconductor device in a second embodiment of the invention;

FIG. 16 is a cross section of a semiconductor device in which semiconductor chips have the same size;

FIG. 17 is a cross section of a semiconductor device according to a third embodiment:

FIG. 18 is a cross section of a semiconductor device according to a fourth embodiment:

FIG. 19A is a hemihedral view showing the structure of a semiconductor chip according to a fifth embodiment;

FIG. 19B is a cross section of the semiconductor chip, taken along line B-B in FIG. 19A;

FIG. 19C is a cross section of the semiconductor chip, taken long line C-C in FIG. 19A;

FIG. 20 is a cross section showing how a porous Si layer is made in a semiconductor chip manufacturing process according to a sixth embodiment;

FIG. 21A is a cross section of an SiGe layer and an Si layer, taken along line A-A in FIG. 21B;

FIG. 21 B is a top plan view showing how the SiGe layer and the Si layer are made in the semiconductor chip manufacturing process according to the sixth embodiment;

FIG. 22A is a cross section of a p⁺-Si layer, taken along line A-A in FIG. 22B;

FIG. 22B is a top plan view showing how the p⁺-Si layer is made in the semiconductor chip manufacturing process according to the sixth embodiment;

FIG. 23 is a cross section showing how a BOX (Buried Oxide) layer is made in the semiconductor chip manufacturing process according to the sixth embodiment;

FIG. 24A is a cross section of a contact hole, taken along line A-A in FIG. 24B;

FIG. 24B is a cross section showing how the contact hole is made in the semiconductor chip manufacturing process according to the sixth embodiment;

FIG. 25 is a cross section showing a gate oxidizing step in the semiconductor chip manufacturing process according to the sixth embodiment;

FIG. 26A is a cross section of a contact hole, taken along line A-A in FIG. 26B;

FIG. 26B is a cross section showing how the contact hole is made in a source/drain contact hole in the semiconductor chip manufacturing process according to the sixth example;

FIG. 27 is a cross section showing how arsenide (As) ions are implanted in the semiconductor chip manufacturing process according to the sixth example; and

FIG. 28 is a cross section showing how a substrate is thinned and oxidized in the semiconductor chip manufacturing process according to the sixth example.

### DETAILED DESCRIPTION OF THE INVENTION

### First Embodiment

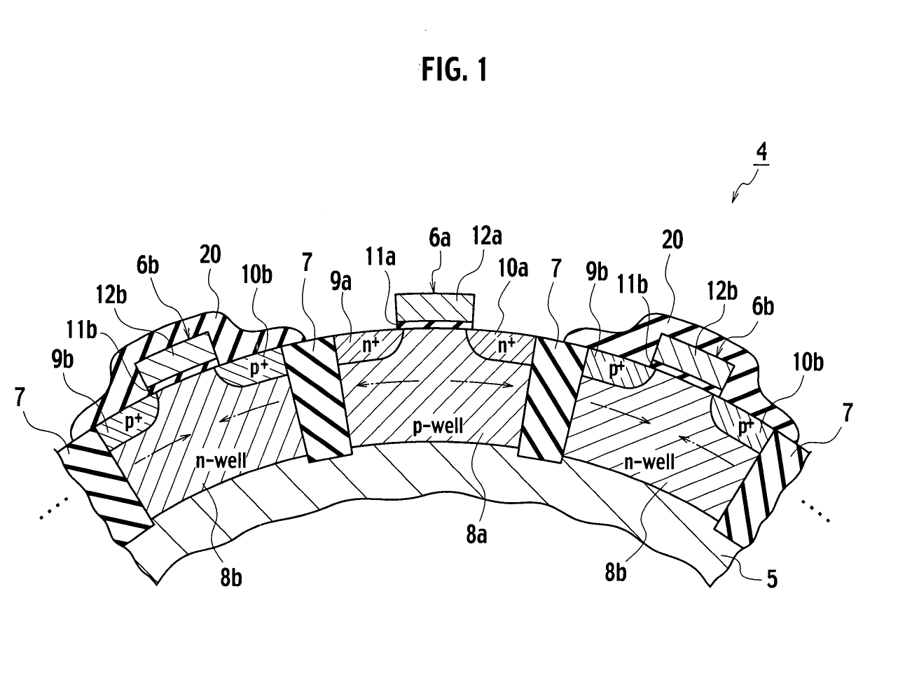

Referring to FIG. 1, a semiconductor integrated circuit 4 (called the “semiconductor chip 4”) includes a substrate 5; a n-channel conductive gate-insulated field effect transistor 6a (called the n-channel conductive IGFET 6a″); and a p-channel conductive gate-insulated field effect transistor 6b (called the p-channel conductive IGFET 6b″). There are a plurality of the n-channel conductive IGFETs 6a and a plurality of the p-channel conductive IGFETs 6b, on the main surface of the substrate. The substrate 5 receives a stress on its main surface. The n-channel conductive IGFET 6a are placed in a first region of the main surface of the substrate 5, and have the first channel conductivity and the carrier mobility raised in response to the first stress. The p-channel conductive IGFET 6b are placed in a second region of the main surface of the substrate 5, have second channel conductivity, and receive a second stress which is opposite to the first stress. The second region is independent from the first region.

In the semiconductor chip 4, the n-channel conductive IGFET 6a and p-channel conductive IGFET 6b are present on the main surface of the substrate 5 via an element isolating region 7.

The n-channel conductive IGFET 6a includes a p-well 8a, a source electrode 9a and a drain electrode 10a, all of which are on the main surface of the substrate 5. A gate electrode 12a is placed on a surface of the p-well 8a via a gate-insulated film 11a.

The p-channel conductive IGFET 6b includes an n-well 8b, a source electrode 9b and a drain electrode 10b, all of which are on the main surface of the substrate 5. A gate electrode 12b is placed on a surface of the n-well 8b via a gate-insulated film 11b.

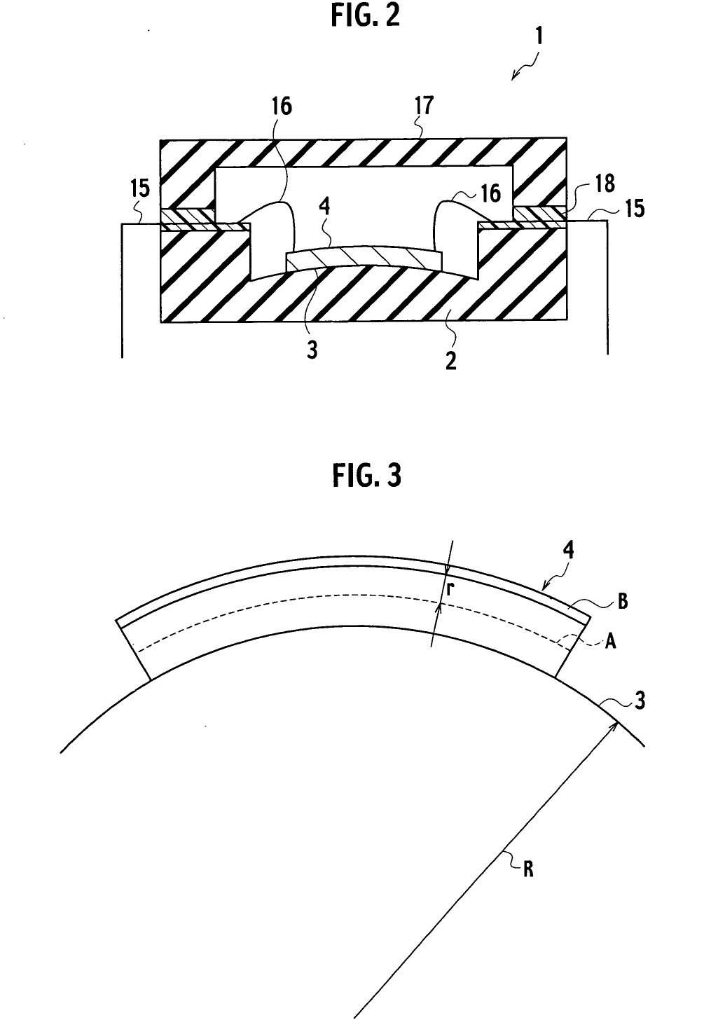

As shown in FIG. 2, a semiconductor device 1 includes an LSI package base 2, semiconductor chip 4, a metal connector 16, a package cap 17, and a sealant 18. The LSI package base 2 houses the semiconductor chip 4 which is bonded on a die pad 3. The metal connector 16 connects a bonding pad of the semiconductor chip 4 and a metal wiring 15 sticking out of the semiconductor device 1. The LSI package cap 17 covers the die pad 3 in the LSI package base 2. The sealant 18 seals a joint between the package cap 17 and LSI package base 2.

The LSI package base 2 and package cap 17 are made of ceramics, for example. A surface of the die pad 3 is metallized by Au in order to reduce an electric contact resistance.

The semiconductor chip 4 is bonded onto the die pad 3 by the Au—Si eutectic alloy making process, for instance. The metal connector 16 is made of Al, and is bonded to a bonding pad on the semiconductor chip 4 and the Al wiring 15 by the supersonic bonding method, for example. The sealant 18 is a low-melting glass, and seals the LSI package when melted.

In the semiconductor device 1, the die pad 3 is curved outwards with a predetermined curvature radius toward the semiconductor chip 4. The semiconductor chip 4 is curved in accordance with the contour of the die pad 3. In this embodiment, the die pad 3 is assumed to be curved in one direction.

Referring to FIG. 3, a strain E on a surface B and a stress P acting on the surface B are expressed by expressions (1) and (2):
E=r/R (1)
P=Yr/R (2)
where R denotes the curvature radius of the die pad 3; B denotes the surface whose vertical distance is “r” from a neutral plane A (free from tension and compression) of the semiconductor chip 4; and Y denotes the Young's modulus.

When the LSI is designed such that the IGFET channel is formed on the surface B, a uni-axial tension will be applied to the IGFET channel.

It is assumed here that the semiconductor chip 4 is constituted by an Si substrate. The semiconductor chip 4 should be thinned to approximately 10 μm to 150 μm in order that it is stretched in accordance with the contour of the die pad 3. For instance, if the semiconductor chip 4 is 100 μm thick, the curvature radius R should be approximately 20 mm in order to keep the semiconductor chip 4 strong. When R is 20 mm based on the expressions (1) and (2), the strain on the surface B is 0.25%, and the stress is 0.32 GPa (where the Young's modulus of Si is assumed to be 130 GPa). When R=130 mm, the strain is 0.039%, and the stress is 0.05 GPa. The electron mobility is anticipated to be raised by approximately 15%.

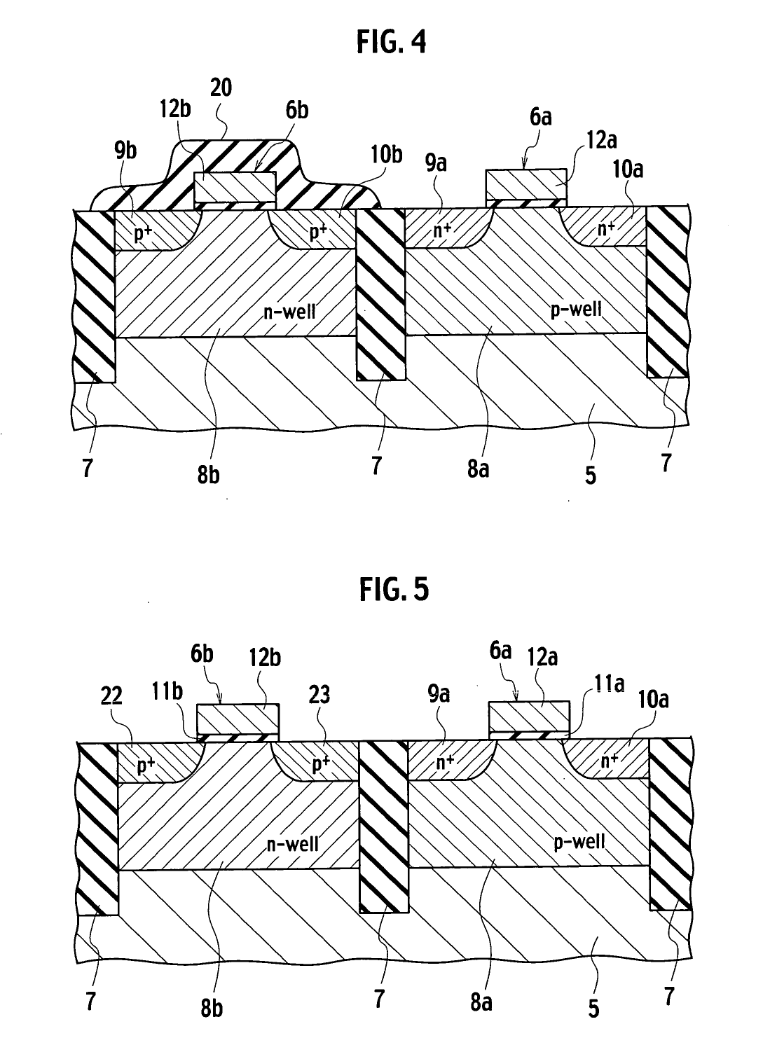

In this embodiment, when mounted on the die pad 3, the thinned semiconductor chip 4 changes its shape in response to the extensible stress applied on the main surface thereof due to the shape of the die pad 3. This mechanical strain raises the carrier mobility of the IGFET channel. Specifically, when the semiconductor chip 4 is mounted on the die pad 3, the channel of the n-type channel conductive IGFET 6a is stretched, which improves the electron mobility. The channel of the n-type channel conductive IGFET 6a is present on the surface B away from the die pad 3 compared to the neutral plane A (shown in FIG. 2) of the semiconductor chip 4. Referring to FIG. 4, a compressive insulating film 20 (e.g., SiO₂ or Si₃N₄ insulating film) is deposited on the p-channel conductive IGFET 6b, and serves as a stress adjuster. Therefore, the compressive stress can be applied to the p-channel conductive IGFET 6b, so that the hole mobility of can be improved by the compressive stress. The stress adjuster is not always limited to the foregoing compressive insulating film, and may be an Si or Ge semiconductor, high melting point metals such as Mo, W, Ti or Ta, or compounds of high melting point metals like MoSi, WSi or TiSi with silicon (silicide). The stress adjuster can be made as a composite film which is constituted by an insulating film covered with any one of the substances mentioned above.

The n-type and p-type channel conductive IGFETs 6a and 6b are formed on the semiconductor chip 4, and the compressive insulating film 20 is provided on the p-type channel conductive IGFET 6b. Therefore, when mounted on the die pad 3, the semiconductor chip 4 except the p-type channel conductive IGFET 6b is stretched due to the convex contour of the die pad 3. In other words, only by mounting the semiconductor chip 4 on the die pad 3, the p-type channel conductive IGFET 6b is compressed by the stress adjuster 20 while the n-type channel conductive IGFET 6a is easily stretched. The n-type and p-type channel conductive IGFETs 6a and 6b are subject to the different kinds of strains, i.e., tension and compression. This structure of the semiconductor chip 4 is effective in improving the mobility of carriers (electrons and holes), and circuit performance of the complementary IGFETs.

The carriers have different levels of mobility in the semiconductor chip 4. Specifically, the electron mobility of the n-type channel conductive IGFET 6a and the hole mobility of the p-type channel conductive IGFET 6b are basically different. By applying the different kinds of stresses to the n-type and p-type channel conductive IGFETs 6a and 6b, it is not necessary to make channels having different degrees of width for the IGFETs 6a and 6b, for example.

In this embodiment, when mounted into the LSI package, the sufficiently thinned semiconductor chip 4 deforms in accordance with the contour of the die pad 3, i.e., the semiconductor chip 4 has its main surface stretched on the die pad 3, and is also compressed on its main surface by the compressive insulating film 20. Thus, the complementary IGFETs can operate at a high speed.

In place of the deposited compressive insulating film 20 made of SiO₂ or the like shown in FIG. 4, a source electrode 22 and a drain electrode 23 (main electrode) of the p-type channel conductive IGFET 6b may be compressive electrodes made of strained SiGe or compressive silicide having a high melting point. Refer to FIG. 5.

Further, the main electrodes of the p-type and n-type channel conductive IGFETs 6b and 6a may be made of compressive silicide having a high melting point. In such a case, the main electrode of the p-type channel conductive IGFET 6b may be thicker than the main electrode of the n-type channel conductive IGFET 6a. In this case, the p-type channel conductive IGFET 6b will not be stretched.

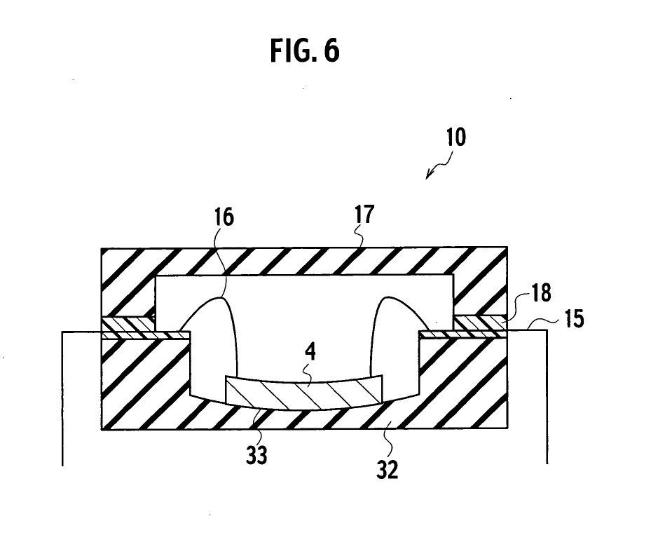

Still further, the die pad 3 (shown in FIG. 2) is convex with respect to the semiconductor chip 4 in this embodiment. Alternatively, the die pad 3 may be concave as shown in FIG. 6. A die pad 33 on an LSI package base 32 of a semiconductor device 10 is concave, and a semiconductor 4 will be curved inwards in accordance with the contour of the die pad 33.

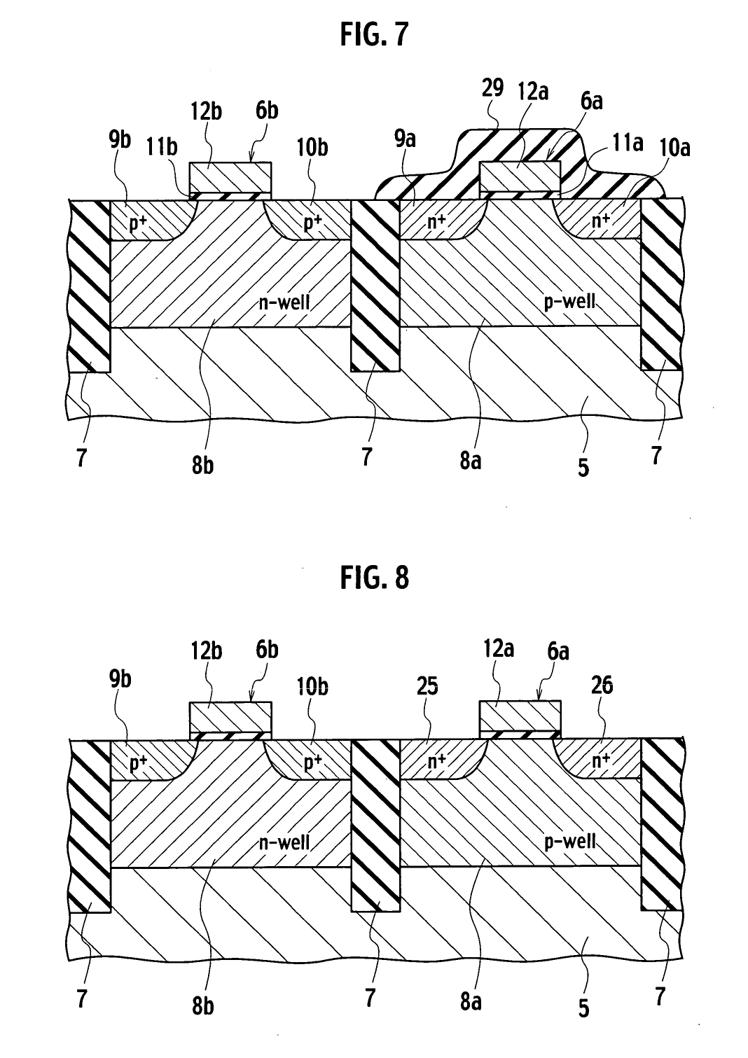

In this case, IGFET channels are uni-axially compressed. The relationship between the applied strain and the stress can be expressed by the foregoing formulas (1) and (2) (i.e., the direction of the tension and compression is reverse in this case). The hole mobility can be improved. It is possible to alleviate a problem related to a conventional CMOS circuit, i.e., a size difference between the n-type and p-type channel conductive IGFETs 6a and 6b (e.g., the p-type channel is three times wider than the n-type channel). This is effective in improving degrees of design freedom. Further, in order to improve the electron mobility, an insulating film 29 made of extensible SiO₂, SiN and so on may be deposited on the n-channel conductive IGFET, as shown in FIG. 7. Still further, a Schottkey transistor including a source electrode 25 and a drain electrode 26 made of extensible metal silicide may be used as shown in FIG. 8. When the semiconductor chip 4 is mounted on the die pad 33 (shown in FIG. 6) and is curved in accordance with the contour of the die pad 33, the n-channel conductive IGFET 6a is stretched because of the extensible insulating film or extensible metal silicide. This is effective in improving the electron mobility.

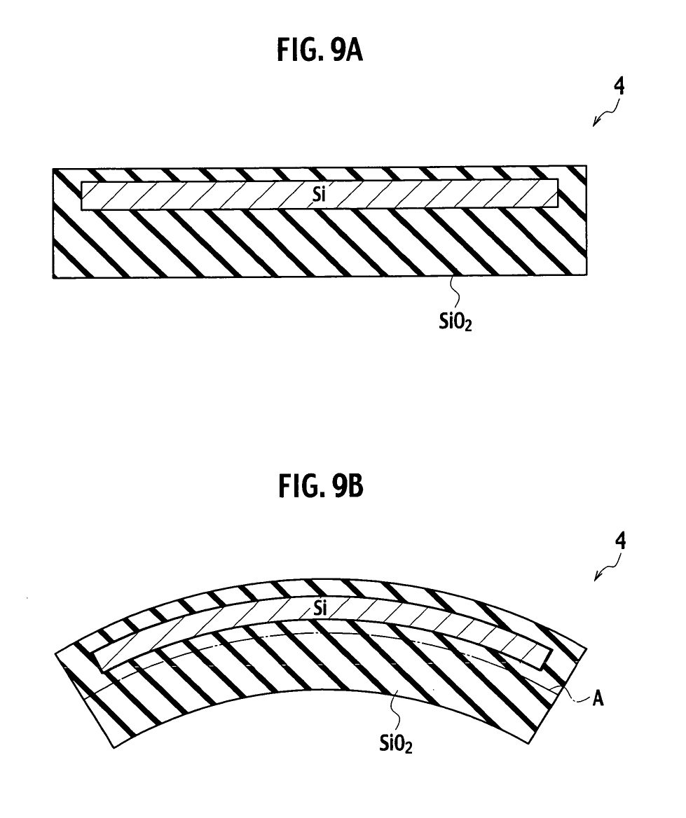

In order to apply a larger strain to the channel region, it is conceivable to wrap the Si region constituting electron devices such as an IGFET with a material having a smaller Young's modulus (such as SiO₂) as shown in FIG. 9A. In such a case, since the opposite ends of a semiconductor chip 4 are fixed, the neutral plane A (shown in FIG. 9B) is parallel to the chip surface and is present at the center of the semiconductor chip 4. If the semiconductor chip 4 is curved as shown in FIG. 9B, the strain applied to the channel region depends upon a distance from the neutral plane A according to the formula (1). For instance, when SiO₂ whose Young's modulus is approximately half of Si is used, the stress on most of the semiconductor chip 4 is approximately half of a stress applied according to the formula (2) when only Si is used. In this case, the curvature radius can be reduced while the semiconductor chip 4 keeps its constant thickness, or the semiconductor chip 4 can be thickened while the curvature radius is maintained constant. Therefore, it is possible to apply a large strain to the channel region. The semiconductor chip 4 having the foregoing structure can be easily manufactured by forming an LSI on an SOI (Silicon on Insulator) substrate. FIG. 9A and FIG. 9B show the example of a semiconductor chip 4 having a convex surface where the IGFET is made. Alternatively, the semiconductor device may have a concave surface.

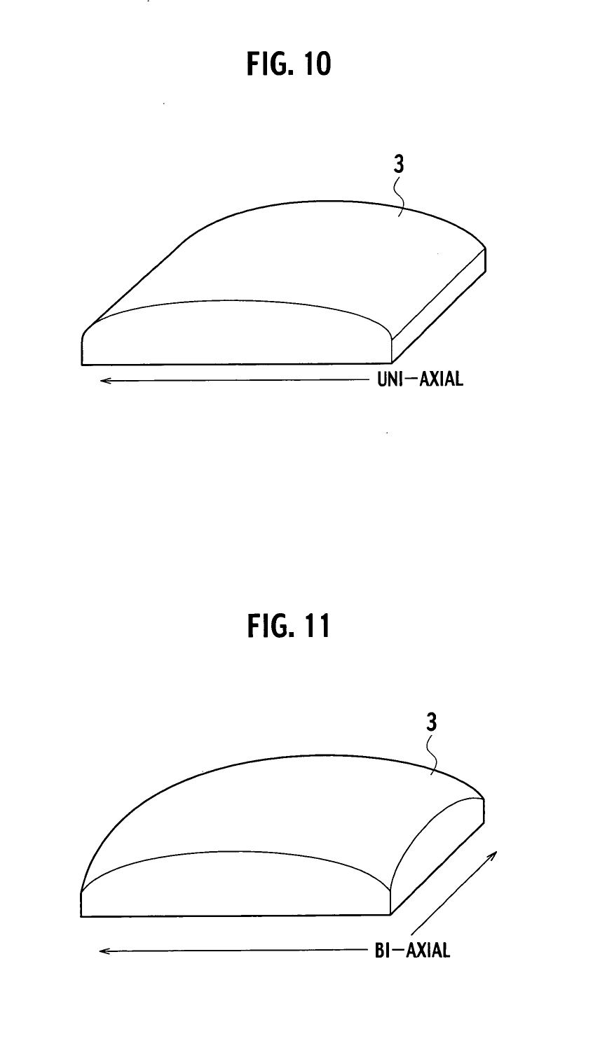

In this example, the die pad 3 is uni-axially curved as shown in FIG. 10. Alternatively, the die pad 3 may be bi-axially curved as shown in FIG. 11 (i.e. the die pad 3 undergoes the bi-axial stress). In other words, the die pad 3 may be shaped as desired. The die pad 3 may be convex (as shown in FIG. 10) or concave (as shown in FIG. 6).

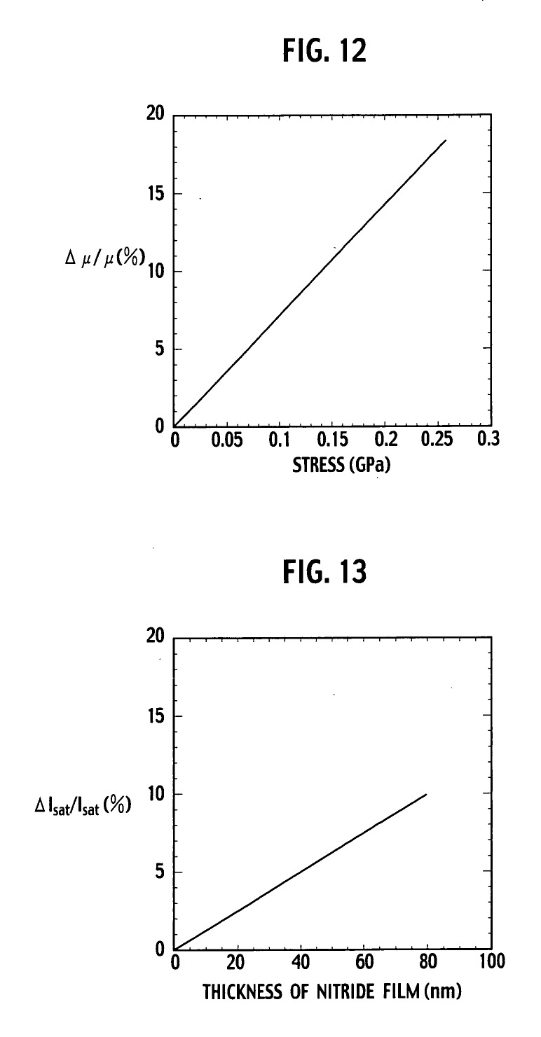

FIG. 12 shows the relationship between the uni-axial compressive stress (in the channel direction) and the improvement of the hole mobility (Δμ/μ:μ). For instance, when a substrate is curved outwards and a compressive stress of 0.15 GPa is applied to the channel region, the hole mobility is raised by approximately 10%.

FIG. 13 shows the relationship between the thickness of a nitride film as a stress adjuster and an electron current Isat. The nitride film should be 80 nm thick in order to improve the electron current progress rate by 10%. For details of the characteristics shown in FIG. 12 and FIG. 13, refer to “Scott E. Thompson, et al., IEEE Transactions on Electron Devices, Vol. 51, No. 11, 2004, p. 1790, A 90-nm Logic Technology Featuring Strained-Silicon”.

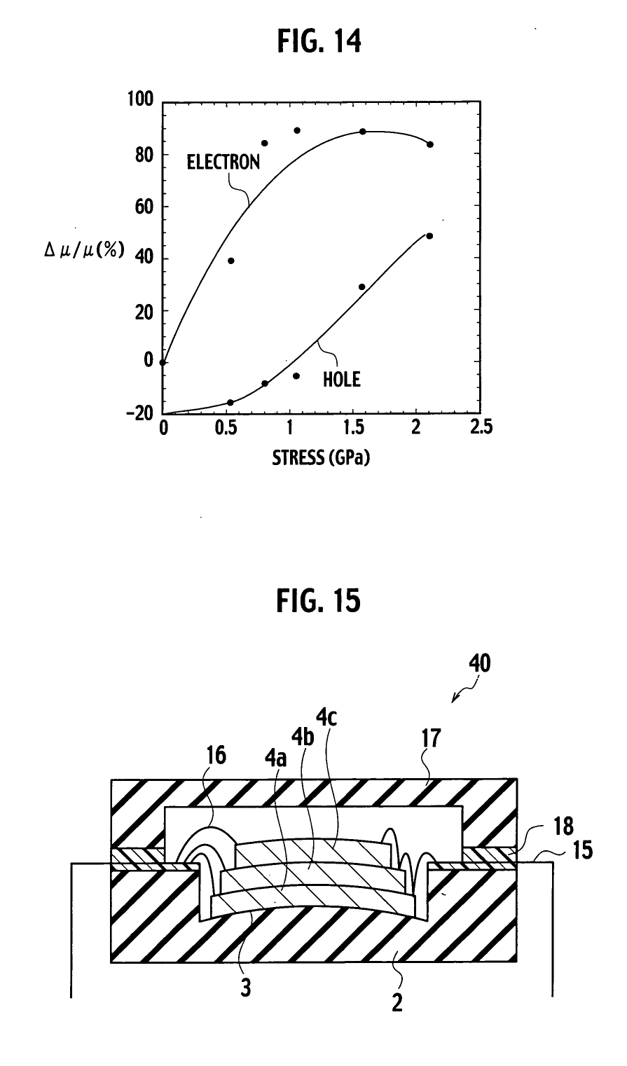

The relationship between the bi-axial stress (extensilibility) and the electron and the hole mobility progress rate is shown in FIG. 14. The larger the extensibility, the higher the electron and hole mobility. However, a stress of 1 GPa or higher cannot be applied in view of the strength of the semiconductor chip 4. The extensible stress is effective for the electrons, and the compressive stress is effective for the holes. For details, refer to “Toshinori Numata, et al., IEDM Technical Digest 2004, p. 177, Performance Enhancement of Partially- and Fully-Depleted Stains-SOI MOSFETs and Characterization of Strained-Device Parameters”.

In the foregoing description, the LSI package is a ceramics substrate. Alternatively, an organic or resin substrate is usable as a package material. So long as the die pad 3 is curved with a certain curvature radius, a lead frame type package is as advantageous as the foregoing LSI package. Further, as for the external connection terminals, the foregoing LSI may be applicable as an LSI package having a ball grid array structure.

### Second Embodiment

In a second embodiment, a semiconductor device 40 is constituted by stacked semiconductor chips 4a to 4c. Referring to FIG. 15, a semiconductor device 40 includes an LSI package base 2 housing the stacked semiconductor chips 4a, 4b and 4c; a convex die pad 3; a metal connector 16; a package cap 17; and a sealant 18.

The convex die pad 3 is formed in the LSI package base 2. The semiconductor chips 4a, 4b and 4c are stacked on the convex die pad 3. The metal connector 16 connects bonding pads of the semiconductor chips 4a, 4b and 4c to a metal wiring 15 connected to an external unit. The package cap 17 covers the convex die pad 3 with respect to the LSI package base 2. The sealant 18 seals a joints between the LSI package base 2 and the package cap 17. These components are configured similarly to those of the semiconductor device 10 of the first embodiment.

In the semiconductor device 40, the semiconductor chips 4a, 4b and 4c are curved outwards on the convex die pad 3 (called the “die pad 3”) having the predetermined curvature radius. The largest semiconductor chip 4a is mounted on the die pad 3, and the semiconductor chips 4b and 4b are stacked on the semiconductor chip 4a one after another.

The semiconductor chips 4a, 4b and 4c are 50 μm thick, respectively, for instance, and are joined using a die bonding material. The joined semiconductor chips 4a, 4b and 4c are bonded onto the die pad 3, so that they can be reliably curved.

The semiconductor chips 4a, 4b and 4c are structured similarly to the semiconductor chip 4 of the first embodiment. Specifically, each of the semiconductor chips 4a, 4b and 4c is provided with an n-channel conductive IGFET 6a and a p-channel conductive IGFET 6b on the surface B which is apart from the die pad 3 compared to the neutral plane A (shown in FIG. 2). A compressive insulating film 20 as a stress adjuster is provided on the p-channel conductive IGFET 6b. In the semiconductor chips 4a, 4b and 4c, the p-channel conductive IGFETs 6b are compressed by the compressive insulating film 20 while the n-channel conductive IGFETs 6a are stretched in accordance with the shape of the die pad 3. Thus, the carrier mobility is improved in both of the n-channel conductive IGFETs 6a and the p-channel conductive IGFETs 6b.

If the semiconductor device 40 is applied to an SiP (System in Package), a high-end chip such as a CPU may be placed at a highest level. In such a case, it is possible to increase a distance from the neutral plane with respect to the stress, which is advantageous in view of applying strain.

In the semiconductor device 40 of the second embodiment, the metal connector 16 is used to connect the bonding pad of the semiconductor chips 4a, 4b and 4c to the metal wiring 15. Alternatively, the semiconductor chips 4a, 4b and 4c may be connected using perforated electrodes 51.

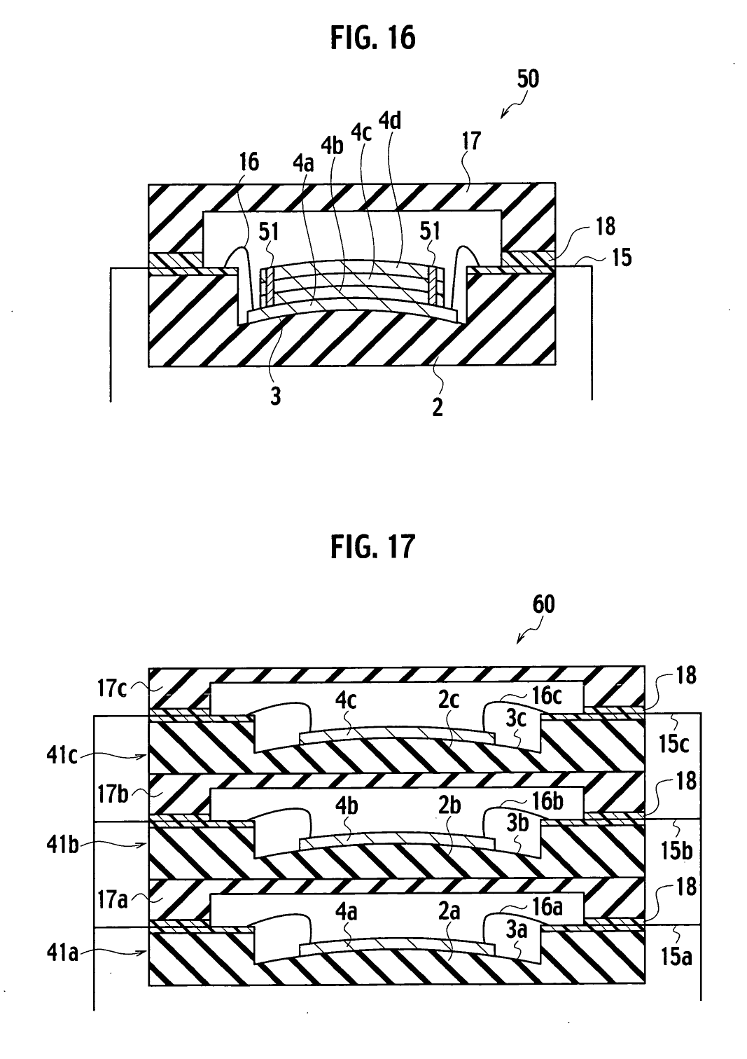

Referring to FIG. 16, a semiconductor device 50 includes a plurality of semiconductor chips 4a, 4b, 4c and 4d mutually connected via the perforated electrodes 51. The perforated electrodes 51 are made as follows: through-holes are made in the semiconductor chips 4a to 4d; metals (such as copper) are embedded in the through-holes; and the semiconductor chips 4a to 4d are then thinned in order that the perforated electrodes 51 stick out. The semiconductor chips 4a to 4d are connected via the through-holes 51. Further, the semiconductor chip 4a on which semiconductor chips 4b to 4d are stacked is connected to the metal wiring 15 using the metal connector 16. The other components of the semiconductor device 50 are identical to those of the semiconductor device 1 of the first embodiment.

The semiconductor chips 4b to 4d connected via the perforated electrode 51 can have the same size. The semiconductor device 50 can prevent the reduction of degree of integration compared to the semiconductor device 40 shown in FIG. 15 since the semiconductor chips 4a to 4d have the same size.

In the second embodiment, the die pad 3 may be curved inward, or may be curved bi-axially as shown in FIG. 11.

Further, in the foregoing description, the LSI package is a ceramics substrate. Alternatively, an organic or resin substrate is usable as a package material. So long as the die pad 3 is curved with a certain curvature radius, an LSI package in the shape of a lead frame is as advantageous as the foregoing LSI package. Further, as for external connection terminals, the foregoing LSI package may be applicable to an LSI package having a ball grid array structure.

### Third Embodiment

In a third embodiment, a semiconductor device 60 includes hierarchical LSI packages 41a, 41b, and 41c. Referring to FIG. 17, the hierarchical LSI package 41a includes a semiconductor chip 4a bonded onto a convex die pad 3a on an LSI package base 2a; the hierarchical LSI package 41b includes a semiconductor chip 4b bonded onto a convex die pad 3b on an LSI package base 2b; and the hierarchical LSI package 41c includes a semiconductor chip 4c bonded onto a convex die pad 3c on an LSI package base 2c. The LSI packages 41a to 41c are stacked one after another.

In each of the LSI packages 41a to 41c, each of bonding pads 3a to 3c of each semiconductor chips 4a to 4c is connected to each of metal wirings 15a to 15c using each of metal connectors 16a to 16c. Each of package caps 17a to 17c covers each of the LSI package bases 2a to 2c using sealants 18. The components of this embodiment are similar to those of the first embodiment.

The die pads 3a, 3b and 3c on the LSI package bases 2a to 2c are curved outwards with a predetermined curvature radius, and receive the semiconductor chips 4a to 4c thereon. The semiconductor chips 4a to 4c are also curved outwards in accordance with the shape of the die pads 3a to 3b.

With the semiconductor device 60, the LSI packages 41a to 41c including the die pads 3a to 3c and semiconductor chips 4a to 4c are stacked one after another. Therefore, strains having the same level can be applied to the semiconductor chips 4a to 4c in the LSI packages 41a to 41c. The third embodiment can remarkably alleviate restrictions on the size and number of semiconductor chips to be stacked similarly to the semiconductor device in which semiconductor chips are directly stacked as shown in FIG. 15.

In this embodiment, the die pads 3a to 3c may be curved inwards as in the first embodiment shown in FIG. 6. Further, they may be bi-axially curved as shown in FIG. 11.

In this embodiment, the LSI packages are ceramics substrates. Alternatively, organic or resin substrates are usable as package materials. So long as the die pads 3a to 3c are curved with the predetermined certain curvature radius, LSI packages in the shape of a lead frame are as advantageous as the foregoing LSI package. Further, as for external connection terminals, the foregoing LSI package may be applicable to an LSI package having a ball grid array structure.

### Fourth Embodiment

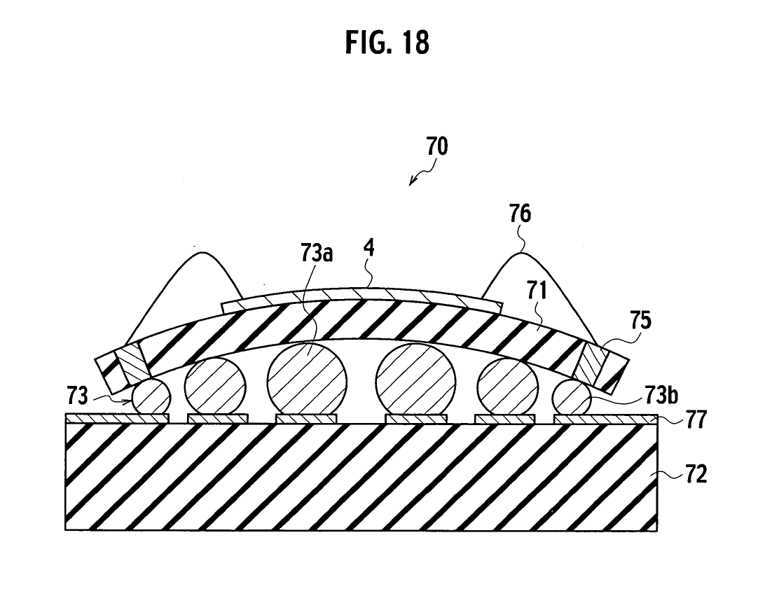

In a fourth embodiment, a semiconductor device 70 has a structure in which an organic substrate 71 with a semiconductor chip 4 bonded thereon is placed on a printed circuit board 72 using solder balls as shown in FIG. 18. Specifically, the semiconductor device 70 includes the semiconductor chip 4; printed circuit board 72 on which the semiconductor chip 4 is mounted; first bump electrodes (solder balls) 73a, and second bump electrodes (solder balls) 73b. The first bump electrodes 73a are placed near the center of a rear surface of the semiconductor chip 4 and near the center of the printed circuit board 72, in accordance with the target shape of the rear surface of the semiconductor chip 4. The second bump electrodes 73b are placed near the peripheral edge of the rear surface of the semiconductor chip 4 and near the peripheral edge of the printed circuit board 72, in accordance with the target shape of the rear surface of the semiconductor chip 4. The second bump electrodes 73b have a size different from that of the first bump electrodes 73a.

Specifically, the semiconductor device 70 includes the semiconductor chip 4, the organic substrate 71 onto which the semiconductor chip 4 is bonded, and a plurality of first and second bump electrodes 73 used to mount the organic substrate 71 on the printed circuit board 72.

The semiconductor chip 4 is 10 μm to 150 μm thick, and the organic substrate 71 is 10 μm to 150 μm thick. The semiconductor chip 4 is bonded onto the organic substrate 71 by the resin bonding process or the like. The organic substrate 71 has a through-hole, into which a metal 75 is embedded (metal 75 is called the “buried metal 75”). The bonding pad of the semiconductor chip 4 is bonded to the buried metal 75 using a metal connector 76, which is made of Al, for instance. Specifically, the bonding pad of the semiconductor chip 4 is bonded to the buried metal 75 by the ultrasonic bonding process.

The buried metal 75 is connected to printed aluminum wirings 77 on the printed circuit board 72 using the first and second bump electrodes (solder balls) 73. The first and second bump electrodes 73 are placed on the printed wirings 77 on the printed circuit board 72 and between positions where the printed wirings 77 and the organic substrate 71 are bonded. The bump electrodes 73 are largest at the center of the semiconductor chip 4 and become gradually small toward the peripheral edge of the printed circuit board 72. In other words, the organic substrate 71 is fixed on the printed circuit board 72.

The thin and light semiconductor chip 4 and the organic substrate 71 are fixedly attached onto the printed circuit board 72 using the bump electrodes 73. The semiconductor chip 4 is curved upwards by a certain curvature radius, so that the channel is stretched, which is effective in improving the electron mobility.

In the fourth embodiment, the organic substrate 71 on which the semiconductor chip 4 is bonded is fixedly attached onto the printed circuit board 72 using the bump electrodes 73 having the different sizes. The semiconductor chip 4 can be curved without making the convex die pad 3 (shown in FIG. 2).

The semiconductor chip 4 can be curved inwards or bi-axially curved depending upon the sizes of the bump electrodes 73.

### Fifth Embodiment

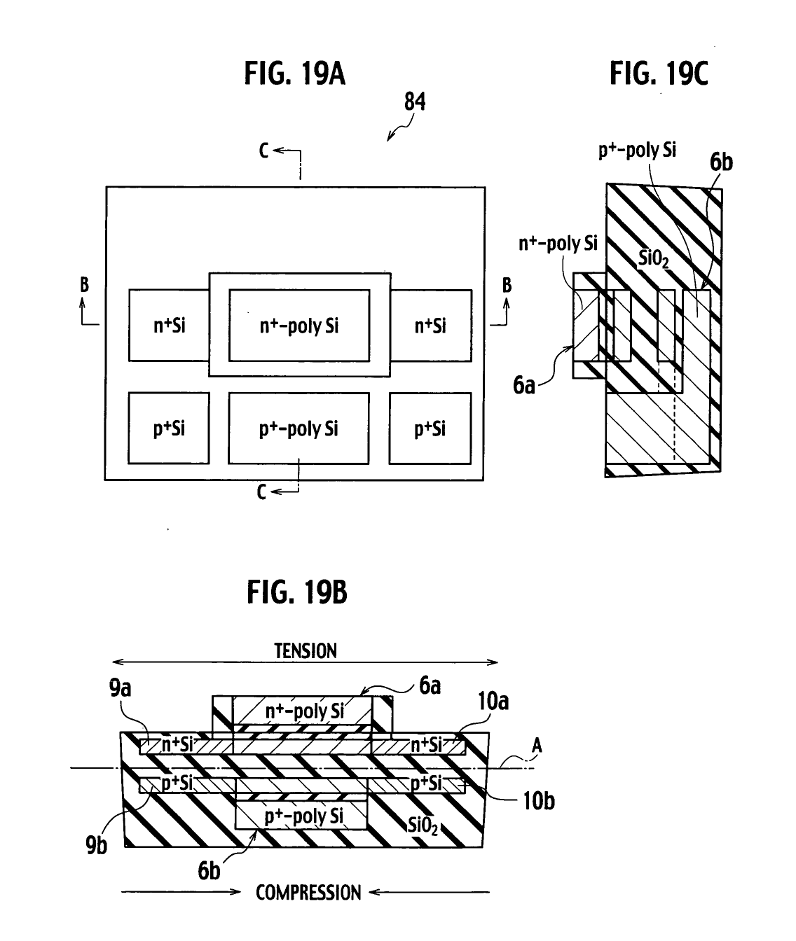

In a fifth embodiment shown in FIG. 19A, FIG. 19B and FIG. 19C, an n-channel conductive IGFET and a p-channel conductive IGFET are placed back to back in a semiconductor chip 84. Referring to FIG. 19B, the n-channel conductive IGFET 6a is placed on an upper part of the neutral plane Awhile the p-channel conductive IGFET 6b is placed on a lower part of the neutral plane A. The neutral plane A divides an area to which a first stress is applied and an area to which a second stress is applied. The p-channel conductive IGFET 6b is accessible on the surface of the semiconductor chip 84. Further, the semiconductor chip 84 is covered by SiO₂ in order to reduce the stress applied thereon. In this case, the semiconductor chip 84 is bonded to a convex die pad 3 (as shown in FIG. 2), so that tension as the first stress is applied to the n-channel conductive IGFET 6a. Further, compression as the second stress is applied to the p-channel conductive IGFET 6b. Therefore, the electron and hole mobility can be improved. In this example, the die pad 3 is uni-axially curved as shown in FIG. 10. Alternatively, the die pad 3 may be bi-axially curved as shown in FIG. 11 (i.e. the die pad 3 undergoes the bi-axial stress).

In one method, the semiconductor chip 84 is manufactured by making the n- and p-channel conductive IGFETs 6a and 6b on a SOI (Silicon On Insulator) substrate, making a through-hole and a perforated electrode, polishing the rear surface of the substrate, and exposing a BOX (Buried Oxide) layer.

Alternatively, the semiconductor chip 84 may be manufactured by aligning wafers, and bonding the wafers using an oxide film.

### Sixth Embodiment

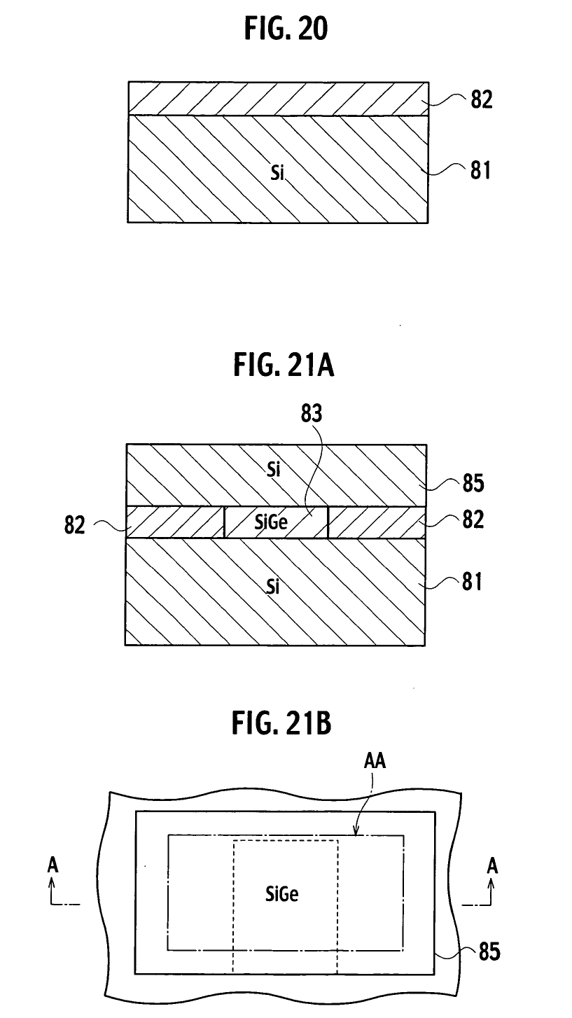

A semiconductor chip may be made by another method. Referring to FIG. 20, an Si substrate 81 is anodized in order to form a porous Si layer 82. A channel making region of the porous Si layer 82 is partially etched by RIE (reactive-ion-etching) as shown in FIG. 21A and FIG. 21B. An SiGe layer 83 is made on the etched part by the epitaxial growth. Thereafter, an Si layer 85 is epitaxially grown on the porous Si layer 82 and SiGe layer 83 using Si of the SiGe layer 83 as a seed crystal.

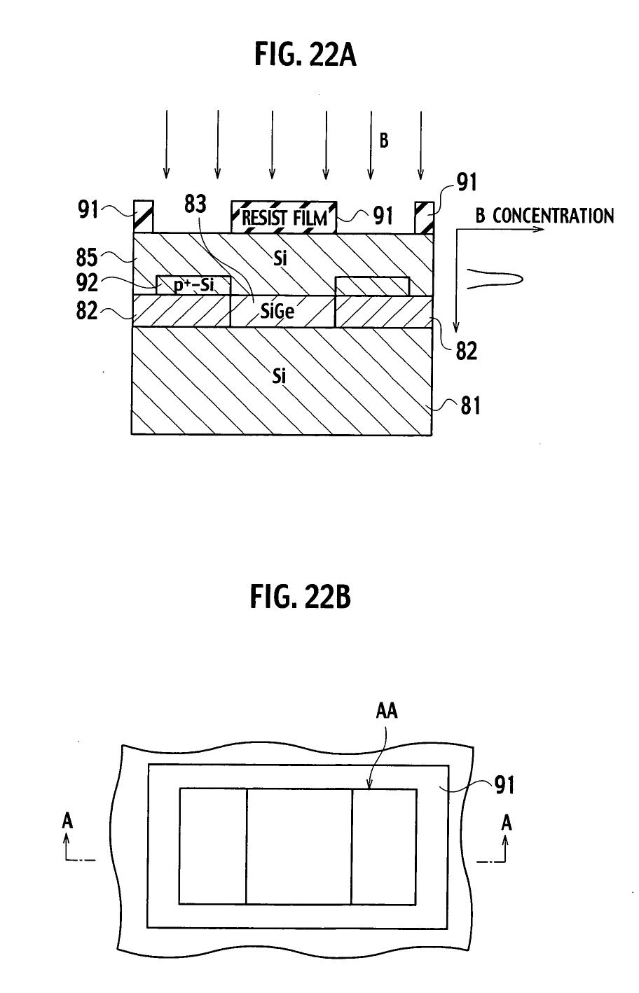

As shown in FIG. 22A and FIG. 22B, a mask 91 is made using a photo-resist film. The mask 91 is used to ion-implant boron into the Si layer 85, so that a p⁺-Si layer 92 is formed in the Si layer 85. In this case, an accelerating energy and implant angle are controlled in order that a peak concentration is present bottom of the Si layer 85.

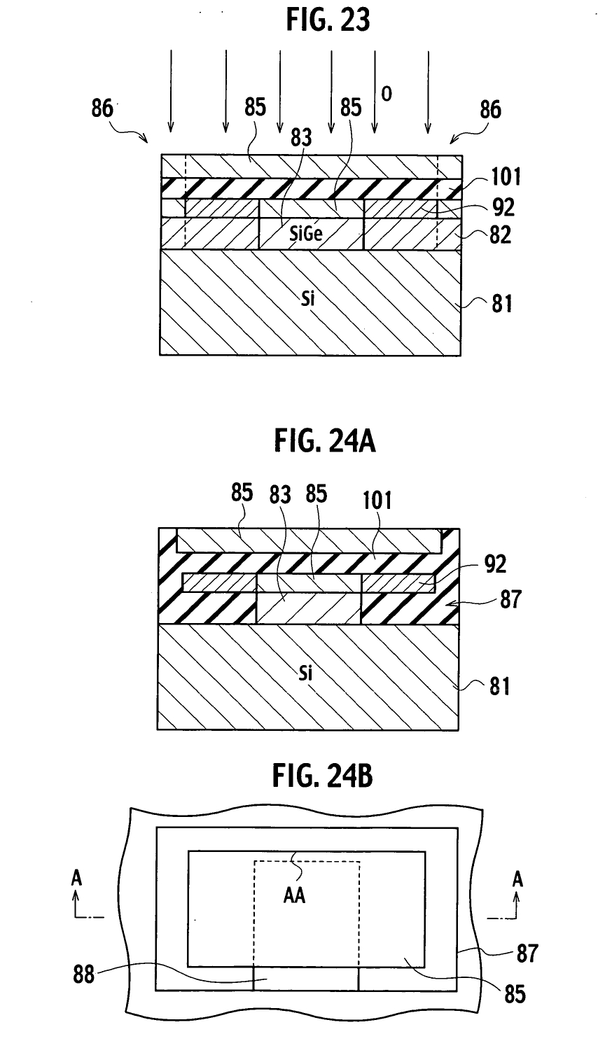

Thereafter, the mask 91 is removed. Oxygen is ion-implanted into the Si layer 85 in order to make a BOX layer 101, i.e., the SIMOX (Separation by Implanted Oxygen) process is utilized. Refer to FIG. 23.

A periphery of an AA region (element isolating region) serving as an IGFET is etched to the porous Si layer 82 by RIE. If oxidization is performed in this state, the porous Si layer 82 is preferentially oxidized. Thereafter, an insulating film 87 is buried in a remaining area of a trench (the periphery 86 of the AA region). Therefore, the insulating film 87 extends between the periphery 86 of the AA region to the porous Si layer 82, as shown in FIG. 24A. Referring to FIG. 24B, to make a contact hole 88 for a gate, the insulating film extending from the periphery 86 of the AA region to the SiGe layer 83 is subject to the RIE from above. Thereafter, the SiGe layer 83 is selectively etched, so that it becomes a hollow. Si above the hollow is three-dimensionally supported by the p⁺-Si layer 92 and BOX layer 101.

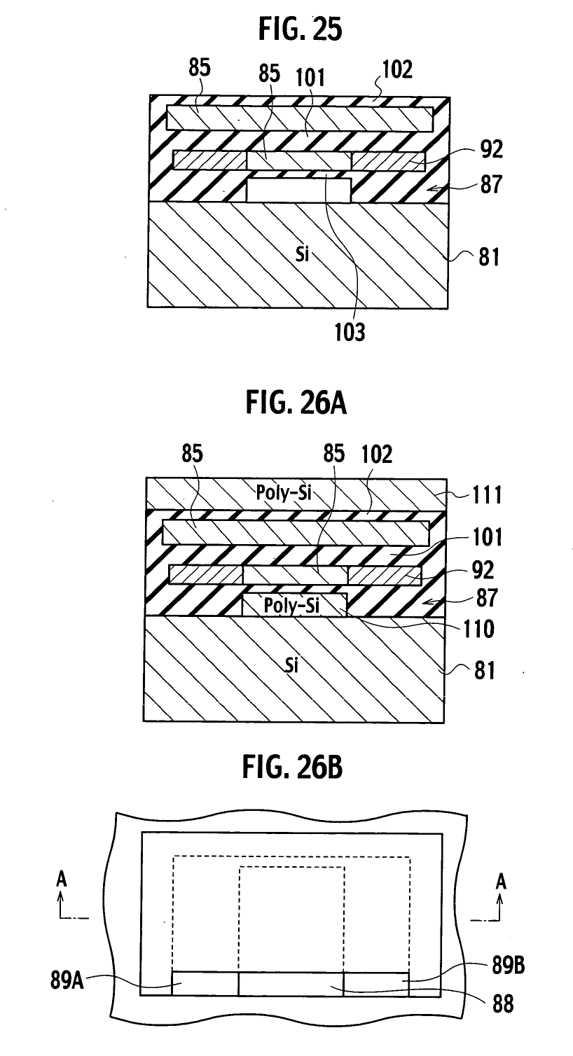

As shown in FIG. 25, the gate oxidization is conducted in order to form gate oxide films 102 and 103. Then, the insulating film extending from the periphery 86 of the AA region to the p⁺-Si layer 92 (shown in FIG. 26A) is subject to the RIE from above, in order to make contact holes 89A and 89B for the source/drain. Next, the p⁺-polycrystalline Si layer is formed by the CVD process, thereby filling the gate, source and drain contact holes. Therefore, the foregoing hollow (shown in FIG. 24A) is filled with Poly Si, so that a gate electrode 110 of the lower IGFET (p-channel conductive IGFET) is formed, and a gate contact is formed by Poly Si filled in the gate contact hole 88. Further, a Poly Si layer 111 is made at the uppermost part of the Si substrate 81 during the CVD process.

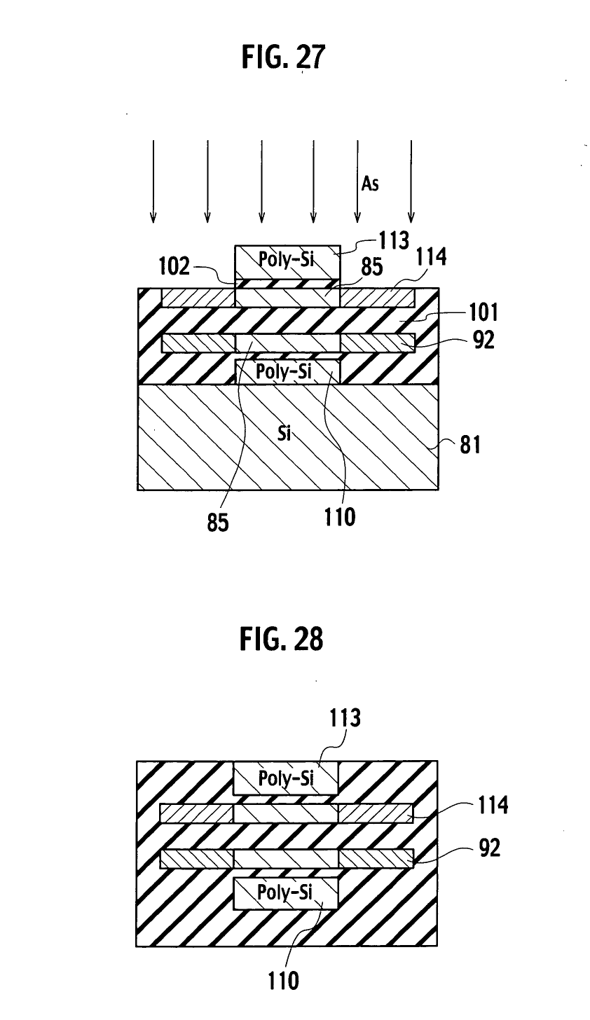

A gate is made for the n-channel as shown in FIG. 27. A gate electrode 113 of an upper IGFET is made from the side of the Poly-Si layer 111 (shown in FIG. 26A). Thereafter, arsenic (As) ions are implanted in order to make an n⁺-Si layer 114 (a source and a drain).

Then, an upper part of the semiconductor chip is post-processed as shown in FIG. 28. The Si substrate 81 is thinned, and is oxidized.

In the sixth embodiment, the n- and p-channel conductive IGFETs can be formed back to back.

As described above, the first stress to improve the carrier mobility is applied to the first channel conductive IGFET while the second stress to improve the carrier mobility is applied to the second channel conductive IGFET. Therefore, it is possible to provide the semiconductor integrated circuit and the semiconductor device in which the performance of the complementary IGFET can be improved.

What is claimed is:

1. A semiconductor integrated circuit comprising:
a substrate having a main surface to which a first stress is applied;
a first channel conductive field effect transistor placed in a first region of the main surface of the substrate, the carrier mobility of a channel of the first channel conductive field effect transistor being improved by the first stress; and
a second channel conductive field effect transistor placed in a second region of the main surface of the substrate, and receiving a second stress at a channel thereof, the second stress being opposite to the first stress, the carrier mobility of the channel of the second channel conductive field effect transistor being improved by the second stress, and the second region being independent from the first region.

2. The semiconductor integrated circuit of claim 1, wherein the second stress is applied by a stress adjuster provided on the second channel conductive field effect transistor.

3. The semiconductor integrated circuit of claim 2, wherein the stress adjuster is a thin film.

4. The semiconductor integrated circuit of claim 2, wherein the stress adjuster also functions as a source electrode and a drain electrode of the second channel conductive field effect transistor.

5. The semiconductor integrated circuit of claim 4, wherein the stress adjuster is an insulator, a semiconductor, a metal, or a compound of a semiconductor and metal.

6. The semiconductor integrated circuit of claim 4, wherein the source electrode and the drain electrode of the second channel conductive field effect transistor is thicker than a source electrode and a drain electrode of the first channel conductive field effect transistor.

7. The semiconductor integrated circuit of claim 1, wherein the first stress is bi-axial.

8. A semiconductor integrated circuit comprising:
a substrate having a main surface which is subject to a compressive stress;
a p-channel conductive field effect transistor placed on a first region of the main surface of the substrate; and
a n-channel conductive field effect transistor placed on a second region of the main surface of the substrate, the second region being independent from the first region.

9. The semiconductor integrated circuit of claim 8, wherein the compressive stress is bi-axial.

10. The semiconductor integrated circuit of claim 8, wherein the compressive stress is produced on the main surface of the substrate curved by a predetermined curvature radius.

11. A semiconductor integrated circuit comprising:
a stressed substrate;
a first channel conductive field effect transistor placed over a neutral plane of the stress of the substrate, and receiving a first stress; and
a second channel conductive field effect transistor placed under the neutral plane of the stress of the substrate, and receiving a second stress opposite to the first stress.

12. A semiconductor device comprising:
a curved die pad; and
the semiconductor integrated circuit of claim 1, the semiconductor integrated circuit being curved in accordance with a contour of the die pad and being stressed.

13. The semiconductor device of claim 12, wherein the die pad is curved outward.

14. The semiconductor device of claim 12, wherein the die pad is curved inward.

15. The semiconductor device of claim 12, wherein the die pad is curved in one direction.

16. The semiconductor device of claim 12, wherein the die pad is curved in two directions.

17. The semiconductor device of claim 13, wherein a plurality of semiconductor integrated circuits are stacked.

18. The semiconductor device of claim 17, wherein the semiconductor integrated circuits become smaller in a stacking direction.

19. A semiconductor device comprising:
the semiconductor integrated circuit defined in claim 1;
a printed circuit board on which the semiconductor integrated circuit are mounted;
first bump electrodes provided between a rear surface of the substrate of the semiconductor integrated circuit and a center of a front surface of the printed circuit board, the first bump electrode being shaped in accordance with a target shape of the substrate; and
second bump electrodes provided at peripheral areas of the rear surface of the substrate and the front surface of the printed circuit board, the second bump electrode being shaped in accordance with the target shape of the substrate, and having a size different from a size of the first bump electrodes.
